(19) United States
(12) Patent Application Publication
(10) Pub. No.: US 2017/0267824 A1
(43) Pub. Date: Sep. 21, 2017

(54) PREPREG COMPOSITE CONTAINING A CROSSLINKED AROMATIC POLYESTER

(71) Applicant: Ticona LLC, Florence, KY (US)

(72) Inventor: Young Shin Kim, Erlanger, KY (US)

(21) Appl. No.: 15/430,611

(22) Filed: Feb. 13, 2017

Related U.S. Application Data
(60) Provisional application No. 62/310,907, filed on Mar. 21, 2016.

(51) Int. Cl. C08J 5/24; H05K 1/03; H05K 1/09; C08J 5/04

(52) U.S. Cl. CPC C08J 5/24; C08J 5/043; H05K 1/0373; H05K 1/09; C08J 2367/04; C08J 2367/06; H05K 2201/0145

(57) ABSTRACT

A prepreg composite that comprises a fibrous substrate and polymer composition impregnated within the substrate is provided. The substrate has a thickness of from about 5 to about 500 micrometers and contains glass fibers. The polymer composition includes a crosslinked thermoset aromatic polyester. The aromatic polyester includes repeating units derived from an aromatic hydroxycarboxylic acid, aromatic dicarboxycarboxylic acid, aromatic diol, aromatic amide, aromatic amine, or a combination thereof.

### RELATED APPLICATION

The present application claims priority to U.S. Provisional Application Ser. No. 62/310,907, filed on Mar. 21, 2016, which is incorporated herein in its entirety by reference thereto.

### BACKGROUND OF THE INVENTION

Printed circuit boards (PCBs) can be composed of various kinds of materials that provide the characteristic attributes necessary for the electrical and mechanical operation of products for different applications. For example, printed circuit boards typically contain a conductive layer (e.g., copper film) stacked together with a dielectric material. Pre-impregnated composites (“prepregs”) are often employed as the dielectric material in certain types of printed circuit boards (e.g., rigid or rigid-flex boards). For example, one prepreg that is commonly employed is known as FR-4, which is fabricated from a woven fiberglass cloth that is impregnated with an epoxy resin. While having certain beneficial properties, the conventional FR-4 prepregs often exhibit poor dimensional stability and a high coefficient of thermal expansion (CTE). To help address these issues, attempts have also been made to add crosslinked polyphenylene oxide (“PPO”) and/or certain inorganic fillers (e.g., silica) to the epoxy resin. Although these additives can provide some benefit, they tend to increase the dielectric constant of the composition, which can limit their use in applications requiring relatively fast signal speeds. As such, a need exists for an improved composite material for use in printed circuit boards, as well as other possible applications.

### SUMMARY OF THE INVENTION

In accordance with one embodiment of the present invention, a prepreg composite is disclosed that comprises a fibrous substrate having a thickness of from about 5 to about 500 micrometers and containing glass fibers. A polymer composition is impregnated within the fibrous substrate and that includes a crosslinked thermoset aromatic polyester. The aromatic polyester includes repeating units derived from an aromatic hydroxycarboxylic acid, aromatic dicarboxycarboxylic acid, aromatic diol, aromatic amide, aromatic amine, or a combination thereof.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 is a schematic view of one embodiment the prepreg composite of the present invention;

FIG. 2 is a schematic view of another embodiment the prepreg composite of the present invention; and

FIG. 3 is a schematic view of yet another embodiment the prepreg composite of the present invention.

### DETAILED DESCRIPTION

It is to be understood that the terminology used herein is for the purpose of describing particular embodiments only and is not intended to limit the scope of the present invention.

“Alkyl” refers to monovalent saturated aliphatic hydrocarbyl groups having from 1 to 10 carbon atoms and, in some embodiments, from 1 to 6 carbon atoms. “C_{x-y}alkyl” refers to alkyl groups having from x to y carbon atoms. This term includes, by way of example, linear and branched hydrocarbyl groups such as methyl (CH₃), ethyl (CH₃CH₂), n-propyl (CH₃CH₂CH₂), isopropyl ((CH₃)₂CH), n-butyl (CH₃CH₂CH2CH₂), isobutyl ((CH₃)₂CHCH₂), sec-butyl ((CH₃)(CH₃CH₂)CH), t-butyl ((CH₃)₃C), n-pentyl (CH₃CH₂CH₂CH₂CH₂), and neopentyl ((CH₃)₃CCH₂).

“Alkenyl” refers to a linear or branched hydrocarbyl group having from 2 to 10 carbon atoms and in some embodiments from 2 to 6 carbon atoms or 2 to 4 carbon atoms and having at least 1 site of vinyl unsaturation (>C═C<). For example, (Cₓ-C_{y})alkenyl refers to alkenyl groups having from x to y carbon atoms and is meant to include for example, ethenyl, propenyl, 1,3-butadienyl, and so forth.

“Alkynyl” refers to refers to a linear or branched monovalent hydrocarbon radical containing at least one triple bond. The term “alkynyl” may also include those hydrocarbyl groups having other types of bonds, such as a double bond.

“Aryl” refers to an aromatic group of from 3 to 14 carbon atoms and no ring heteroatoms and having a single ring (e.g., phenyl) or multiple condensed (fused) rings (e.g., naphthyl or anthryl). For multiple ring systems, including fused, bridged, and spiro ring systems having aromatic and non-aromatic rings that have no ring heteroatoms, the term “Aryl” applies when the point of attachment is at an aromatic carbon atom (e.g., 5,6,7,8 tetrahydronaphthalene-2-yl is an aryl group as its point of attachment is at the 2-position of the aromatic phenyl ring).

“Cycloalkyl” refers to a saturated or partially saturated cyclic group of from 3 to 14 carbon atoms and no ring heteroatoms and having a single ring or multiple rings including fused, bridged, and spiro ring systems. For multiple ring systems having aromatic and non-aromatic rings that have no ring heteroatoms, the term “cycloalkyl” applies when the point of attachment is at a non-aromatic carbon atom (e.g. 5,6,7,8,-tetrahydronaphthalene-5-yl). The term “cycloalkyl” includes cycloalkenyl groups, such as adamantyl, cyclopropyl, cyclobutyl, cyclopentyl, cyclooctyl, and cyclohexenyl.

“Halo” or “halogen” refers to fluoro, chloro, bromo, and iodo.

“Haloalkyl” refers to substitution of alkyl groups with 1 to 5 or in some embodiments 1 to 3 halo groups.

“Heteroaryl” refers to an aromatic group of from 1 to 14 carbon atoms and 1 to 6 heteroatoms selected from oxygen, nitrogen, and sulfur and includes single ring (e.g., imidazolyl) and multiple ring systems (e.g., benzimidazol-2-yl and benzimidazol-6-yl). For multiple ring systems, including fused, bridged, and spiro ring systems having aromatic and non-aromatic rings, the term “heteroaryl” applies if there is at least one ring heteroatom and the point of attachment is at an atom of an aromatic ring (e.g., 1,2,3,4-tetrahydroquinolin-6-yl and 5,6,7,8-tetrahydroquinolin-3-yl). In some embodiments, the nitrogen and/or the sulfur ring atom(s) of the heteroaryl group are optionally oxidized to provide for the N oxide (N→O), sulfinyl, or sulfonyl moieties. Examples of heteroaryl groups include, but are not limited to, pyridyl, furanyl, thienyl, thiazolyl, isothiazolyl, triazolyl, imidazolyl, imidazolinyl, isoxazolyl, pyrrolyl, pyrazolyl, pyridazinyl, pyrimidinyl, purinyl, phthalazyl, naphthylpryidyl, benzofuranyl, tetrahydrobenzofuranyl, isobenzofuranyl, benzothiazolyl, benzoisothiazolyl, benzotriazolyl, indolyl, isoindolyl, indolizinyl, dihydroindolyl, indazolyl, indolinyl, benzoxazolyl, quinolyl, isoquinolyl, quinolizyl, quianazolyl, quinoxalyl, tetrahydroquinolinyl, isoquinolyl, quinazolinonyl, benzimidazolyl, benzisoxazolyl, benzothienyl, benzopyridazinyl, pteridinyl, carbazolyl, carbolinyl, phenanthridinyl, acridinyl, phenanthrolinyl, phenazinyl, phenoxazinyl, phenothiazinyl, and phthalimidyl.

“Heterocyclic” or “heterocycle” or “heterocycloalkyl” or “heterocyclyl” refers to a saturated or partially saturated cyclic group having from 1 to 14 carbon atoms and from 1 to 6 heteroatoms selected from nitrogen, sulfur, or oxygen and includes single ring and multiple ring systems including fused, bridged, and spiro ring systems. For multiple ring systems having aromatic and/or non-aromatic rings, the terms “heterocyclic”, “heterocycle”, “heterocycloalkyl”, or “heterocyclyl” apply when there is at least one ring heteroatom and the point of attachment is at an atom of a non-aromatic ring (e.g., decahydroquinolin-6-yl). In some embodiments, the nitrogen and/or sulfur atom(s) of the heterocyclic group are optionally oxidized to provide for the N oxide, sulfinyl, sulfonyl moieties. Examples of heterocyclyl groups include, but are not limited to, azetidinyl, tetrahydropyranyl, piperidinyl, N-methylpiperidin-3-yl, piperazinyl, N-methylpyrrolidin-3-yl, 3-pyrrolidinyl, 2-pyrrolidon-1-yl, morpholinyl, thiomorpholinyl, imidazolidinyl, and pyrrolidinyl.

It should be understood that the aforementioned groups encompass unsubstituted groups, as well as groups substituted with one or more other functional groups as is known in the art. For example, an alkynyl, alkyl, alkenyl, aryl, heteroaryl, cycloalkyl, or heterocyclyl group may be substituted with from 1 to 8, in some embodiments from 1 to 5, in some embodiments from 1 to 3, and in some embodiments, from 1 to 2 substituents selected from alkyl, alkenyl, alkynyl, alkoxy, acyl, acylamino, acyloxy, amino, quaternary amino, amide, imino, amidino, aminocarbonylamino, amidinocarbonylamino, aminothiocarbonyl, aminocarbonylamino, aminothiocarbonylamino, aminocarbonyloxy, aminosulfonyl, aminosulfonyloxy, aminosulfonylamino, aryl, aryloxy, arylthio, azido, carboxyl, carboxyl ester, (carboxyl ester)amino, (carboxyl ester)oxy, cyano, cycloalkyl, cycloalkyloxy, cycloalkylthio, guanidino, halo, haloalkyl, haloalkoxy, hydroxy, hydroxyamino, alkoxyamino, hydrazino, heteroaryl, heteroaryloxy, heteroarylthio, heterocyclyl, heterocyclyloxy, heterocyclylthio, nitro, oxo, thione, phosphate, phosphonate, phosphinate, phosphonamidate, phosphorodiamidate, phosphoramidate monoester, cyclic phosphoramidate, cyclic phosphorodiamidate, phosphoramidate diester, sulfate, sulfonate, sulfonyl, substituted sulfonyl, sulfonyloxy, thioacyl, thiocyanate, thiol, alkylthio, etc., as well as combinations of such substituents.

It is to be understood by one of ordinary skill in the art that the present discussion is a description of exemplary embodiments only, and is not intended as limiting the broader aspects of the present invention.

Generally speaking, the present invention is directed to a prepreg composite that contains a fibrous substrate and a polymer composition that is impregnated within the substrate. By selectively controlling the specific nature of the fibrous substrate and polymer composition, a composite can be formed that exhibits a unique combination of good mechanical properties and heat resistance. The fibrous substrate, for instance, has a thickness of from about 5 to about 500 micrometers and contains glass fibers (e.g., glass fiber cloth).

In addition, the polymer composition contains a crosslinked thermoset aromatic polyester, which includes repeating units derived from an aromatic hydroxycarboxylic acid, aromatic dicarboxycarboxylic acid, aromatic diol, aromatic amide, aromatic amine, or a combination thereof. Due to the manner in which it is formed, the thermoset aromatic polyester and polymer composition may exhibit excellent thermal properties. For example, the polyester and/or polymer composition may have a relatively high melting temperature. The melting temperature may, for example, range from about 200° C. to about 370° C., in embodiments from about 250° C. to about 360° C., in some embodiments from about 280° C. to about 350° C., in some embodiments from about 290° C. to about 335° C., and in some embodiments, from about 300° C. to about 330° C., such as determined by differential scanning calorimetry in accordance with ISO Test No. 11357-2:2013. While having a relatively high melting temperature, the polyester and/or polymer composition may nevertheless maintain a relatively low melt viscosity, such as about 150 Pa-s or less, in some embodiments about 100 Pa-s or less, in some embodiments from about 1 to about 80 Pa-s, and in some embodiments, from about 2 to about 50 Pa-s. Melt viscosity may be determined in accordance with ISO Test No. 11443:2005 at a shear rate of 1000 s⁻¹ and using a Dynisco LCR7001 capillary rheometer. The melt viscosity is also typically determined at a temperature at least 15° C. above the melting temperature (e.g., 300° C., 320° C., or 350° C.). As a result of such properties, the polymer composition is capable of exhibiting good thermal properties while remaining relatively flowable and easy to process, which can provide a great degree of flexibility in the particular type of application method that is employed.

The polymer composition also generally exhibits good electrical properties. For instance, the polymer composition may have a relatively low dielectric constant that allows it to be employed as a heat dissipating material in various electronic applications (e.g., printed circuit boards). For example, the dielectric constant may be about 5.0 or less, in some embodiments from about 0.1 to about 4.5, and in some embodiments, from about 0.2 to about 3.5, as determined by the split post resonator method at a variety of frequencies, such as from about 1 to about 15 GHz (e.g., 1, 2, or 10 GHz). The dissipation factor, a measure of the loss rate of energy, may also be relatively low, such as about 0.0060 or less, in some embodiments about 0.0050 or less, and in some embodiments, from about 0.0010 to about 0.0040, as determined by the split post resonator method at a variety of frequencies, such as from about 1 to about 15 GHz (e.g., 1, 2, or 10 GHz). The dielectric constant (or relative static permittivity) and dissipation factor may be determined using a known split-post dielectric resonator technique, such as described in Baker-Jarvis, et al., IEEE Trans. on Dielectric and Electrical Insulation, 5(4), p. 571 (1998) and Krupka, et al., Proc. 7th International Conference on Dielectric Materials: Measurements and Applications, IEEE Conference Publication No. 430 (September 1996). For example, a plaque sample having a size of 80 mm×80 mm×1 mm may be inserted between two fixed dielectric resonators. The resonator may measure the permittivity component in the plane of the specimen. Five (5) samples may be tested and the average value may be recorded. The split-post resonator can be used to make dielectric measurements in the low gigahertz region, such as 2 GHz.

Various embodiments of the present invention will now be described in more detail.

### I. Polymer Composition

A. Crosslinked Aromatic Polyester

As indicated above, the polymer composition of the present invention includes a thermoset crosslinked aromatic polyester, which may contain aromatic ester repeating units generally represented by the following Formula (I):

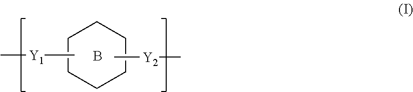

wherein,

ring B is a substituted or unsubstituted 6-membered aryl group (e.g., 1,4-phenylene or 1,3-phenylene), a substituted or unsubstituted 6-membered aryl group fused to a substituted or unsubstituted 5- or 6-membered aryl group (e.g., 2,6-naphthalene), or a substituted or unsubstituted 6-membered aryl group linked to a substituted or unsubstituted 5- or 6-membered aryl group (e.g., 4,4-biphenylene); and

Y₁ and Y₂ are independently O, C(O), NH, C(O)HN, or NHC(O), wherein at least one of Y₁ and Y₂ are C(O).

Examples of aromatic ester repeating units that are suitable for use in the present invention may include, for instance, aromatic dicarboxylic repeating units (Y₁ and Y₂ in Formula I are C(O)), aromatic hydroxycarboxylic repeating units (Y₁ is O and Y₂ is C(O) in Formula I), as well as various combinations thereof.

Aromatic hydroxycarboxylic repeating units may, for instance, be employed that are derived from aromatic hydroxycarboxylic acids, such as, 4-hydroxybenzoic acid; 4-hydroxy-4′-biphenylcarboxylic acid; 2-hydroxy-6-naphthoic acid; 2-hydroxy-5-naphthoic acid; 3-hydroxy-2-naphthoic acid; 2-hydroxy-3-naphthoic acid; 4′-hydroxyphenyl-4-benzoic acid; 3′-hydroxyphenyl-4-benzoic acid; 4′-hydroxyphenyl-3-benzoic acid, etc., as well as alkyl, alkoxy, aryl and halogen substituents thereof, and combination thereof. Particularly suitable aromatic hydroxycarboxylic acids are 6-hydroxy-2-naphthoic acid (“HNA”) and 4-hydroxybenzoic acid (“HBA”). When employed, for instance, the repeating units derived from HNA may constitute from about 15 mol. % to about 60 mol. %, in some embodiments from about 20 mol. % to about 50 mol. %, and in some embodiments, from 30 mol. % to about 45 mol. % of the polymer, while the repeating units derived from HBA may constitute from about 20 mol. % to about 65 mol. %, in some embodiments from about 30 mol. % to about 60 mol. %, and in some embodiments, from about 40 mol. % to about 55% of the polymer.

Aromatic dicarboxylic repeating units may also be employed that are derived from aromatic dicarboxylic acids, such as terephthalic acid, isophthalic acid, 2,6-naphthalenedicarboxylic acid, diphenyl ether-4,4′-dicarboxylic acid, 1,6-naphthalenedicarboxylic acid, 2,7-naphthalenedicarboxylic acid, 4,4′-dicarboxybiphenyl, bis(4-carboxyphenyl)ether, bis(4-carboxyphenyl)butane, bis(4-carboxyphenyl)ethane, bis(3-carboxyphenyl)ether, bis(3-carboxyphenyl)ethane, etc., as well as alkyl, alkoxy, aryl and halogen substituents thereof, and combinations thereof. Particularly suitable aromatic dicarboxylic acids may include, for instance, 2,6-naphthalenedicarboxylic acid (“NDA”), terephthalic acid (“TA”), and isophthalic acid (“IA”). When employed, for instance, repeating units derived from NDA, IA, and/or TA may constitute from about 1 mol. % to about 50 mol. %, in some embodiments from about 2 mol. % to about 45 mol. %, and in some embodiments, from 5 mol. % to about 40 mol. % of the polymer. In certain embodiments, however, the polymer may be generally free of such dicarboxylic acid repeating units, such as about 5 mol. % or less, and in some embodiments, about 2 mol. % or less (e.g., 0 mol. %).

Other repeating units may also be employed in the polymer. In certain embodiments, for instance, repeating units may be employed that are derived from aromatic diols, such as hydroquinone, resorcinol, 2,6-dihydroxynaphthalene, 2,7-dihydroxynaphthalene, 1,6-dihydroxynaphthalene, 4,4′-dihydroxybiphenyl (or 4,4′-biphenol), 3,3′-dihydroxybiphenyl, 3,4′-dihydroxybiphenyl, 4,4′-dihydroxybiphenyl ether, bis(4-hydroxyphenyl)ethane, etc., as well as alkyl, alkoxy, aryl and halogen substituents thereof, and combinations thereof. Particularly suitable aromatic diols may include, for instance, hydroquinone (“HQ”) and 4,4′-biphenol (“BP”). When employed, repeating units derived from aromatic diols (e.g., HQ and/or BP) typically constitute from about 1 mol. % to about 40 mol. %, in some embodiments from about 2 mol. % to about 30 mol. %, and in some embodiments, from about 5 mol. % to about 25% of the polymer. Repeating units may also be employed, such as those derived from aromatic amides (e.g., acetaminophen (“APAP”)) and/or aromatic amines (e.g., 4-aminophenol (“AP”), 3-aminophenol, 1,4-phenylenediamine, 1,3-phenylenediamine, etc.). When employed, repeating units derived from aromatic amides (e.g., APAP) and/or aromatic amines (e.g., AP) typically constitute from about 0.1 mol. % to about 20 mol. %, in some embodiments from about 0.5 mol. % to about 15 mol. %, and in some embodiments, from about 1 mol. % to about 10% of the polymer. It should also be understood that various other monomeric repeating units may be incorporated into the polymer. For instance, in certain embodiments, the polymer may contain one or more repeating units derived from non-aromatic monomers, such as aliphatic or cycloaliphatic hydroxycarboxylic acids, dicarboxylic acids (e.g., cyclohexane dicarboxylic acid), diols, amides, amines, etc. Of course, in other embodiments, the polymer may be “wholly aromatic” in that it lacks repeating units derived from non-aromatic (e.g., aliphatic or cycloaliphatic) monomers.

In certain embodiments of the present invention, the aromatic polyester may be “naphthenic-rich” to the extent that it contains a high content of repeating units derived from naphthenic hydroxycarboxylic acids and/or naphthenic dicarboxylic acids, such as 2,6-naphthalenedicarboxylic acid (“NDA”), 6-hydroxy-2-naphthoic acid (“HNA”), or combinations thereof. That is, the total amount of repeating units derived from naphthenic hydroxycarboxylic and/or dicarboxylic acids (e.g., NDA, HNA, or a combination of HNA and NDA) is typically more than about 15 mol. %, in some embodiments more than about 20 mol. %, in some embodiments more than about 25 mol. %, and in some embodiments, from 25 mol. % to about 50 mol. % of the polymer. In one particular embodiment, for instance, the aromatic polyester may contain repeating units derived from HNA, HBA, BP and/or HQ, as well as various other optional constituents. The repeating units derived from HNA may constitute from about 15 mol. % to about 60 mol. %, in some embodiments from about 20 mol. % to about 50 mol. %, and in some embodiments, from 30 mol. % to about 45 mol. % of the polymer. The repeating units derived from HBA may constitute from about 20 mol. % to about 65 mol. %, in some embodiments from about 30 mol. % to about 60 mol. %, and in some embodiments, from about 40 mol. % to about 55% of the polymer. The repeating units derived from BP and/or HQ may likewise constitute from about 1 mol. % to about 40 mol. %, in some embodiments from about 2 mol. % to about 30 mol. %, and in some embodiments, from about 5 mol. % to about 25% of the polymer.

If desired, the aromatic polyester may also contain one or more functional groups (e.g., terminal groups) that help facilitate crosslinking. For example, the aromatic polyester may contain hydroxyl functional groups, acyloxy functional groups, aromatic cyclic functional groups, diene functional groups, etc. Hydroxyl functional groups may, for instance, be introduced into the polymer through the use of a stoichiometric excess of aromatic diols during polymerization. For example, the ratio of the total moles of hydroxyl groups in the monomers to the total moles of carboxyl groups in the monomers may be from about 1.01 to about 1.50, in some embodiments from about 1.05 to about 1.40, and in some embodiments, from about 1.10 to about 1.30. In certain embodiments, this ratio may be achieved by controlling the amount of aromatic diol and aromatic hydroxycarboxylic acid monomers used during polymerization. For instance, the ratio of the total moles of aromatic diols to the total moles of aromatic hydroxycarboxylic acids may be from about 0.10 to about 0.15, and in some embodiments, from about 0.11 to about 0.13. Acyloxy functional groups can be introduced through the use of acylating agents, such as acetic anhydride. Cyclic and conjugated diene functional groups may be introduced in a similar manner. For instance, conjugated diene functional groups may be introducing using a conjugated diene monomer, such as 1-methyl-2,4-cyclopentadiene-1-yl) methanol).

Regardless of its particular monomer content, the aromatic polyester may generally be prepared by introducing the precursor monomers into a reactor vessel to initiate a polycondensation reaction. The particular conditions and steps employed in such reactions may be described in more detail in U.S. Pat. No. 4,161,470 to Calundann; U.S. Pat. No. 5,616,680 to Linstid, III, et al.; U.S. Pat. No. 6,114,492 to Linstid, III, et al.; U.S. Pat. No. 6,514,611 to Shepherd, et al.; and WO 2004/058851 to Waggoner. The vessel employed for the reaction is not especially limited, although it is typically desired to employ one that is commonly used in reactions of high viscosity fluids. Examples of such a reaction vessel may include a stirring tank-type apparatus that has an agitator with a variably-shaped stirring blade, such as an anchor type, multistage type, spiral-ribbon type, screw shaft type, etc., or a modified shape thereof. Further examples of such a reaction vessel may include a mixing apparatus commonly used in resin kneading, such as a kneader, a roll mill, a Banbury mixer, etc.

If desired, the polymerization reaction may proceed through the acetylation of the monomers as known in art. Acetylation may occur in in a separate reactor vessel, or it may occur in situ within the polymerization reactor vessel. When separate reactor vessels are employed, one or more of the monomers may be introduced to the acetylation reactor and subsequently transferred to the melt polymerization reactor. Likewise, one or more of the monomers may also be directly introduced to the reactor vessel without undergoing pre-acetylation. Acetylation may be accomplished by adding an acetylating agent (e.g., acetic anhydride) to one or more of the monomers. One particularly suitable technique for acetylating monomers may include, for instance, charging precursor monomers (e.g., HNA, HBA, BP, and/or HQ) and acetic anhydride into a reactor and heating the mixture to acetylize a hydroxyl group of the monomers (e.g., forming acetoxy).

Acetylation is generally initiated at temperatures of about 90° C. During the initial stage of the acetylation, reflux may be employed to maintain vapor phase temperature below the point at which acetic acid byproduct and anhydride begin to distill. Temperatures during acetylation typically range from between 90° C. to 150° C., and in some embodiments, from about 110° C. to about 150° C. If reflux is used, the vapor phase temperature typically exceeds the boiling point of acetic acid, but remains low enough to retain residual acetic anhydride. For example, acetic anhydride vaporizes at temperatures of about 140° C. Thus, providing the reactor with a vapor phase reflux at a temperature of from about 110° C. to about 130° C. is particularly desirable. To ensure substantially complete reaction, an excess amount of acetic anhydride may be employed. The amount of excess anhydride will vary depending upon the particular acetylation conditions employed, including the presence or absence of reflux. The use of an excess of from about 1 to about 10 mole percent of acetic anhydride, based on the total moles of reactant hydroxyl groups present is not uncommon.

After any optional acetylation is complete, the resulting composition may be melt-polymerized. Although not required, this is typically accomplished by transferring the acetylated monomer(s) to a separator reactor vessel for conducting a polycondensation reaction. If desired, one or more of the precursor monomers used to form the aromatic polyester may be directly introduced to the melt polymerization reactor vessel without undergoing pre-acetylation. Other components may also be included within the reaction mixture to help facilitate polymerization. For instance, a catalyst may be optionally employed, such as metal salt catalysts (e.g., magnesium acetate, tin(I) acetate, tetrabutyl titanate, lead acetate, sodium acetate, potassium acetate, etc.) and organic compound catalysts (e.g., N-methylimidazole). Such catalysts are typically used in amounts of from about 50 to about 500 parts per million based on the total weight of the recurring unit precursors. The catalyst is typically added to the acetylation reactor rather than the polymerization reactor, although this is by no means a requirement.

In some embodiments, the melt polymerized polymer may also be subjected to a subsequent solid-state polymerization method to further increase its molecular weight. For instance, solid-state polymerization may be conducted in the presence of a gas (e.g., air, inert gas, etc.). Suitable inert gases may include, for instance, include nitrogen, helium, argon, neon, krypton, xenon, etc., as well as combinations thereof. The solid-state polymerization reactor vessel can be of virtually any design that will allow the polymer to be maintained at the desired solid-state polymerization temperature for the desired residence time. Examples of such vessels can be those that have a fixed bed, static bed, moving bed, fluidized bed, etc. The temperature at which solid-state polymerization is performed may vary, but is typically within a range of from about 250° C. to about 300° C. The polymerization time will of course vary based on the temperature and target molecular weight. In most cases, however, the solid-state polymerization time will be from about 2 to about 12 hours, and in some embodiments, from about 4 to about 10 hours.

The aromatic polyester of the present invention may be crosslinked in a variety of different ways. In certain embodiments, for example, a crosslinking agent may be introduced into the backbone of the polymer during polymerization of the precursor monomers (e.g., aromatic hydroxycarboxylic acid, aromatic diol, etc.). In such embodiments, the crosslinking agent may be supplied at any stage of the polymerization process, such as to the acetylation reactor vessel, melt polymerization reactor vessel, solid state polymerization reactor vessel, etc., as well as combinations of the foregoing. Although it may be introduced at any stage, it is typically desired to supply the crosslinking agent before and/or during melt polymerization so that it forms a reaction mixture with the precursor monomers. The relative amount of the crosslinking agent in the reaction mixture may be from about 0.1 to about 10 parts, in some embodiments from about 0.5 to about 8 parts, and in some embodiments, from about 1 to about 5 parts by weight relative to 100 parts by weight of the reaction mixture. Crosslinking agents may, for example, constitute from about 0.1 wt. % to about 10 wt. %, in some embodiments from about 0.5 wt. % to about 8 wt. %, and in some embodiments, from about 1 wt. % to about 5 wt. % of the reaction mixture. Precursor monomers may likewise constitute from about 90 wt. % to about 99.9 wt. %, in some embodiments from about 92 wt. % to about 99.5 wt. %, and in some embodiments, from about 95 wt. % to about 99 wt. % of the reaction mixture. While referred to in terms of the reaction mixture, it should also be understood that the ratios and weight percentages may also be applicable to the final polymer. That is, the parts by weight of the crosslinking agent relative to 100 parts by weight of the aromatic polyester and the percentage of the crosslinking agents in the final polymer may be within the ranges noted above.

Besides being introduced into the polymer backbone during polymerization, the crosslinking agent may also be reacted with the aromatic polyester after it is formed. The crosslinking agent may, for instance, contain a functional group that is reactive with a functional group present on the aromatic polyester (e.g., hydroxyl, acyloxy, conjugated diene, etc.). If desired, this reaction may occur in the presence of an organic solvent, such as glycols (e.g., propylene glycol, butylene glycol, triethylene glycol, hexylene glycol, polyethylene glycols, ethoxydiglycol, and dipropyleneglycol); alcohols (e.g., methanol, ethanol, n-propanol, and isopropanol); triglycerides; ethyl acetate; acetone; triacetin; acetonitrile, tetrahydrafuran; xylenes; formaldehydes (e.g., dimethylformamide, “DMF”); etc. In such embodiments, the reaction of the aromatic polyester and the crosslinking agent may occur at a relatively low temperature, such as from about 100° C. to about 250° C., in some embodiments from about 110° C. to about 200° C., and in some embodiments, from about 120° C. to about 180° C. Of course, other techniques may also be employed to induce the desired crosslinking reaction. For example, melt blending techniques may be employed in which the crosslinking agent is blended and reacted with the aromatic polyester while it is in a melt phase (e.g., within an extruder). In such embodiments, the reaction of the aromatic polyester and the crosslinking agent may occur at a temperature of from about 200° C. to about 450° C., in some embodiments from about 250° C. to about 400° C., and in some embodiments, from about 275° C. to about 350° C. Regardless of the particular method employed, the relative amount of the crosslinking agent may be from about 0.01 to about 10 parts, in some embodiments from about 0.05 to about 8 parts, and in some embodiments, from about 0.1 to about 5 parts by weight relative to 100 parts by weight of the aromatic polyester. The crosslinking agents may, for example, constitute from about 0.01 wt. % to about 10 wt. %, in some embodiments from about 0.05 wt. % to about 8 wt. %, and in some embodiments, from about 0.1 wt. % to about 5 wt. % of the reaction mixture. Aromatic polyesters may likewise constitute from about 90 wt. % to about 99.99 wt. %, in some embodiments from about 92 wt. % to about 99.95 wt. %, and in some embodiments, from about 95 wt. % to about 99.9 wt. % of the reaction mixture.

Any of a variety of suitable crosslinking agents may generally be employed in the present invention. Suitable crosslinking agents may include, for instance, alkynyl crosslinking agents; reactive compounds containing a functional group, such as an epoxy group, maleimide group, ester group, carbonyl group, acid anhydride group, etc.; and so forth. Typically, the crosslinking agent has relatively low molecular weight so that it does not adversely impact the melt rheology of the resulting polymer. For example, the crosslinking agent typically has a molecular weight of about 3,000 grams per mole or less, in some embodiments from about 20 to about 2,000 grams per mole, in some embodiments from about 30 to about 1,000 grams per mole, and in some embodiments, from about 50 to about 500 grams per mole. The melting temperature of the crosslinking agent may also be relatively low, such as about 150° C. or less, in some embodiments from about 20° C. to about 130° C., and in some embodiments, from about 30° C. to about 100° C.

Particularly suitable crosslinking agents for use in the present invention may, for instance, include maleimide compounds. In certain cases, for instance, a bismaleimide may be employed that has the following general formula:

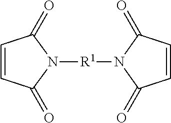

wherein R¹ is a substituted or unsubstituted, alkyl, alkenyl, alkynyl, cycloalkyl, aryl, heteroaryl, heterocyclyl, or a combination thereof.

In certain embodiments, for instance, R¹ may be an aryl group that contains one or more aromatic rings having from 6 to 15 carbon atoms, and in some embodiments, from 6 to 10 carbon atoms (e.g., phenyl). The aryl group may generally contain any number of aromatic rings desired. For instance, in one embodiment, a single aromatic ring may be employed. Likewise, in other embodiments, multiple aromatic rings may be employed, such as from 2 to 6, and in some embodiments, from 2 to 4. If desired, one or more linking groups may also be employed between adjacent aromatic rings and/or between an aromatic ring and the nitrogen atom of the imide group. Examples of such linking groups may include, for instance, ether (—O—), thioether (—S—), acyl (—C(O)—), ester (—C(O)O—), sulfonyl (—SO₂—), alkyl (e.g., —CH₂—), alkoxy (e.g., —OCH₂—, —OCH₂CH₂—O—, etc.), amide (—NHCO—), etc.

Particularly suitable bismaleimides are those in which the aryl group of R¹ contains two aromatic rings (e.g., phenyl). Examples of such biaromatic bismaleimides include, for instance, 4,4′-dimaleimidophenylmethane (diphenylmethane bismaleimide), N,N′-(3,3′-dimethyl-4,4′-biphenylylene) bismaleimide, 3,3′-dichloro-4,4′-diphenylmethane bismaleimide, 3,3′-dimethyl-4,4′ diphenylmethane bismaleimide, 3,3′-dimethoxy-4,4′-diphenylmethane bismaleimide, 4,4′-diphenylsulfide bismaleimide, 4,4′-diphenylether bismaleimide, 3,3′-benzophenone bismaleimide, 3, 3′-dimethyl-5,5′-diethyl-4,4′-diphenylmethane bismaleimide, etc. Yet other suitable bismaleimides may also be employed. For instance, some examples of suitable bismaleimides in which the aryl group of R¹ contains only one aromatic ring (e.g., phenyl) include 4-methyl-1,3-phenylene bismaleimide, 1, 3-phenylene bismaleimide, 1,4-phenylene bismaleimide, 1,2-phenylene bismaleimide, naphthalene-1,5-bismaleimide, 4-chloro-1,3-phenylene bismaleimide, etc. Likewise, some examples of suitable bismaleimides in which the aryl group of R¹ contains three or more aromatic rings (e.g., phenyl) include 2,2-bis [4-(4-maleimide phenoxy)phenyl]propane, bis[4-maleimide(4-phenoxyphenyl)sulfone, 1,3-bis(4-maleimide phenoxy)benzene, 1,3-bis(3-maleimide phenoxy)benzene, etc.

Of course, as noted above, bismaleimides may also be employed in which R¹ contains an alkyl and/or cycloalkyl group. Examples of such compounds may include, for instance, 1,6-bismaleimide-(2,2,4-trimethyl) hexane, 1,6-bismaleimide-(2,4,4-trimethyl)hexane, N,N′-decamethylene bismaleimide, N,N′-decamethylene bismaleimide, N,N′-octamethylene bismaleimide, N,N′-heptamethylene bismaleimide, N, N′-hexamethylene bismaleimide, N,N′-pentamethylene bismaleimide, N, N′-tetramethylene bismaleimide, N,N′-trimethylene bismaleimide, N,N′-ethylene bismaleimide, N,N′-(oxydimethylene) bismaleimide, etc.

Another suitable type of crosslinking agent that may be employed in the present invention is an alkynyl crosslinking agent. The alkynyl crosslinking agent may be monoaromatic, biaromatic, etc. For example, in certain embodiments, a monoaromatic alkynyl crosslinking agent may be employed, such as 3-phenylprop-2-ynoic acid (or phenyl propiolic acid), methyl-3-phenylprop-2-ynoate, 4-phenylbut-3-ynoic acid, 5-phenylpent-2-en-4-ynoic acid, 3-phenylprop-2-ynamide, etc. In other embodiments, a biaromatic alkynyl crosslinking agent may be employed, such as those having the following general Formula (III):

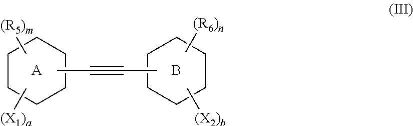

wherein,

Ring A and B are independently a 6-membered aryl or heteroaryl optionally fused to a 6-membered aryl or heteroaryl;

X₁ is Y₁R₁;

X₂ is Y₂R₂;

Y₁ and Y₂ are independently O, C(O), OC(O), C(O)O, S, NR₃, C(O)NR₃, or NR₃C(O);

R₁, R₂, and R₃ are independently hydrogen, hydroxyl, alkyl, aryl, heteroaryl, cycloalkyl, or heterocyclyl;

R₅ and R₆ are independently alkynyl, alkyl, alkenyl, aryl, heteroaryl, cycloalkyl, heterocyclyl, halo, or haloalkyl;

a is from 1 to 5, in some embodiments from 1 to 3, and in some embodiments, from 1 to 2 (e.g., 1);

b is from 0 to 5, in some embodiments from about 0 to 3, and in some embodiments, from 0 to 2 (e.g., 0);

m is from 0 to 4, in some embodiments from about 0 to 3, and in some embodiments, from 0 to 2 (e.g., 0); and

n is from 0 to 5, in some embodiments from about 0 to 3, and in some embodiments, from 0 to 2 (e.g., 0).

The alkynyl (e.g., ethynyl) functional group may be located at a variety of positions of the Rings A and B, such as at the 4 position (para position), 3 position (meta position), or 2 position (ortho position). In particular embodiments, however, the alkynyl functional group is located at the 4 position, such as depicted below in general Formula (IV). In certain embodiments, Ring A and B may also be a 6-membered aryl, such as benzene; 6-membered heteroaryl, such as pyridine, pyrazine, pyrimidine, pyridazine, etc.; 6-membered aryl fused to a 6-membered aryl, such as naphthalene; 6-membered aryl fused to a 6-membered heteroaryl, such as quinoline, isoquinoline, quinoxaline, quinazoline, cinnoline, etc.; as well as combinations thereof. As indicated above, Rings A and B may be unsubstituted (m and/or n is 0) or substituted (m and/or n is 1 or more). In particular embodiments, however, m and n are 0 such that the aromatic alkynyl crosslinking agent is provided by general formula (IV):

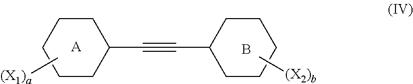

Y₁ and/or Y₂ in Formula I or II may be O, OC(O), C(O)O, NH, C(O)NH, or NHC(O), and R₁ and/or R₂ may be H, OH, or alkyl (e.g., methyl). For example, Y₁R₁ and/or Y₂R₂ may be OH, O-alkyl (e.g., OCH₃), OC(O)-alkyl (e.g., OC(O)CH₃), C(O)OH, C(O)O-alkyl (e.g., C(O)OCH₃), OC(O)OH, OC(O)O-alkyl (e.g., OC(O)OCH₃), NH₂, NH-alkyl (e.g., NHCH₃), C(O)NH₂, C(O)NH-alkyl (e.g., C(O)NHCH₃), NHC(O)H, NHC(O)-alkyl (e.g., NHC(O)CH₃), NHC(O)OH, NHC(O)O— alkyl (e.g., NHC(O)OCH₃), etc. Further, in certain embodiments, as in Formula (III) and (II) may be equal to 1, and b may be equal to 0. Desirably, Rings A and B may also be phenyl so that the resulting compounds are considered biphenyl alkynyl crosslinking agents. Specific embodiments of suitable biphenyl alkynyl crosslinking agents may include, for instance, 4-phenylethynyl acetanilide (a is 1, Y₁ is NHC(O), and R₁ is CH₃); 4-phenylethynyl benzoic acid (b is 0, a is 1, Y is C(O)O, R₁ is H); methyl 4-phenylethynyl benzoate (b is 0, a is 1, Y is C(O)O, R₁ is CH₃); 4-phenylethynyl phenyl acetate (b is 0, a is 1, Y is OC(O), and R₁ is CH₃); 4-phenylethynyl benzamide (b is 0, a is 1, Y is C(O)NR₃, R₁ is H, R₃ is H); 4-phenylethynyl aniline (b is 0, a is 1, Y₁ is NR₃, R₁ is H, and R₃ is H); N-methyl-4-phenylethynyl aniline (b is 0, a is 1, Y is NR₃, R₁ is H, and R₃ is CH₃); 4-phenylethynyl phenyl carbamic acid (b is 0, a is 1, Y is NR₃C(O), R₁ is OH, and R₃ is H); 4-phenylethynyl phenol (b is 0, a is 1, Y is O, and R₁ is H); 3-phenylethynyl benzoic acid (b is 0, a is 1, Y is C(O)O, R₁ is H); 3-phenylethynyl aniline (b is 0, a is 1, Y₁ is NR₃, R₁ is H, and R₃ is H); 3-phenylethynyl phenyl acetate (b is 0, a is 1, Y is OC(O), and R₁ is CH₃); 3-phenylethynyl phenol (b is 0, a is 1, Y is O, and R₁ is H); 3-phenylethynyl acetanilide (a is 1, Y is NHC(O), and R₁ is CH₃); 4-carboxyphenylethynyl benzoic acid (a and b are 1, Y and Y₂ are C(O)O, and R₁ and R₂ are H); 4-aminophenylethynyl aniline (a and b are 1, Y₁ and Y₂ are NR₃, and R₁, R₂ and R₃ are H); and so forth. Particularly suitable are 4-phenylethynyl benzoic acid, 4-phenylethynyl aniline, 4-phenylethynyl phenyl acetate, 4-phenylethynyl acetanilide, and 4-phenylethynyl phenol.

The alkynyl crosslinking agent may possess a high alkynyl functionality. The degree of alkynyl functionality for a given molecule may be characterized by its “alkynyl equivalent weight”, which reflects the amount of a compound that contains one molecule of an alkynyl functional group and may be calculated by dividing the molecular weight of the compound by the number of alkynyl functional groups in the molecule. For example, the crosslinking agent may contain from 1 to 6, in some embodiments from 1 to 4, and in some embodiments, from 1 to 2 alkynyl functional groups per molecule (e.g., 1). The alkynyl equivalent weight may likewise be from about 10 to about 1,000 grams per mole, in some embodiments from about 20 to about 500 grams per mole, in some embodiments from about 30 to about 400 grams per mole, and in some embodiments, from about 50 to about 300 grams per mole. In one embodiment, the alkynyl crosslinking agent is a mono-functional compound in that Rings A and B are directly bonded to only one alkynyl group. In such embodiments, m in Formula (III) may be 0.

B. Other Additives

The aromatic polyester of the present invention may be used alone or in combination with various other optional additives to form a polymer composition that can be impregnated into a fibrous substrate to form a composite. Various examples of such additives are described in more detail below.

i. Other Thermoset Resins

If desired, the polymer composition may contain another type of thermoset resin to help improve the insulating and adhesive properties of the composition. Examples of such resins may include, for instance, epoxy resins, acrylates, cyano-acrylates, cyano-esters, urethanes, etc. One particular example of such a resin is an epoxy resin, which typically contains an epoxide and a curing agent. The epoxide may include an organic compound having at least one oxirane ring polymerizable by a ring opening reaction, and can be aliphatic, heterocyclic, cycloaliphatic, and/or aromatic. The epoxide may be a “polyepoxide” in that it contains at least two epoxy groups per molecule, and it may be monomeric, dimeric, oligomeric or polymeric in nature. The backbone of the resin may be of any type, and substituent groups thereon can be any group not having a nucleophilic group or electrophilic group (such as an active hydrogen atom) which is reactive with an oxirane ring. Exemplary substituent groups include halogens, ester groups, ethers, sulfonate groups, siloxane groups, nitro groups, amide groups, nitrile groups, and phosphate groups.

Suitable epoxide resins may include, for instance, the reaction product of bisphenol A and epichlorohydrin, the reaction product of phenol and formaldehyde (novolac resin) and epichlorohydrin, peracid epoxies, glycidyl esters, glycidyl ethers, the reaction product of epichlorohydrin and p-amino phenol, the reaction product of epichlorohydrin and glyoxal tetraphenol, etc. Particularly suitable epoxides have the general structure set forth below in general formula (I):

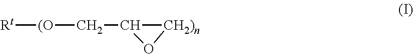

wherein n is 1 or more, and in some embodiments, from 1 to 4, and R′ is an organic residue that may include, for example, an alkyl group, an alkyl ether group, or an aryl group; and n is at least 1. For example, R′ may be a poly(alkylene oxide). Suitable glycidyl ether epoxides of formula (I) include glycidyl ethers of bisphenol A and F, aliphatic diols or cycloaliphatic diols. The glycidyl ether epoxides may include linear polymeric epoxides having terminal epoxy groups (e.g., a diglycidyl ether of polyoxyalkylene glycol) and aromatic glycidyl ethers (e.g., those prepared by reacting a dihydric phenol with an excess of epichlorohydrin). Examples of dihydric phenols include resorcinol, catechol, hydroquinone, and the polynuclear phenols including p,p′-dihydroxydibenzyl, p,p′-dihydroxyphenylsulfone, p,p′-dihydroxybenzophenone, 2,2′-dihydroxyphenyl sulfone, p,p′-dihydroxybenzophenone, 2,2-dihydroxy-1,1-dinaphrhylmethane, and the 2,2′, 2,3′, 2,4′, 3,3′, 3,4′, and 4,4′ isomers of dihydroxydiphenylmethane, dihydroxydiphenyldimethylmethane, dihydroxydiphenylethylmethylmethane, dihydroxydiphenylmethylpropylmethane, dihydroxydiphenylethylphenylmethane, dihydroxydiphenylpropylenphenylmethane, dihydroxydiphenylbutylphenylmethane, dihydroxydiphenyltolylethane, dihydroxydiphenyltolylmethylmethane, dihydroxydiphenyldicyclohexylmethane, and dihydroxydiphenylcyclohexane.

As noted above, the epoxy resin may also include a curing agent capable of cross-linking the epoxide, such as room temperature curing agents, heat-activated curing agents, etc. Examples of such curing agents may include, for instance, imidazoles, imidazole-salts, imidazolines, tertiary amine, and/or primary or secondary amines, such as diamine, diethylene diamine, diethylene triamine, triethylene tetramine, propylene diamine, tetraethylene pentamine, hexaethylene heptamine, hexamethylene diamine, 2-methyl-1,5-pentamethylene-diamine, 4,7,10-trioxatridecan-1,13-diamine, aminoethylpiperazine, etc. In certain embodiments, the curing agent is a polyether amine having one or more amine moieties, including those polyether amines that can be derived from polypropylene oxide or polyethylene oxide.

When employed, additional thermoset resins may constitute from about 10 to about 90 wt. %, in some embodiments from about 20 wt. % to about 85 wt. %, and in some embodiments, from about 30 wt. % to about 80 wt. % of the polymer composition. Nevertheless, one beneficial aspect of the present invention is that good properties may be achieved without the need for various conventional thermoset resins, such as epoxy resins. In fact, in certain embodiments of the present invention, the polymer composition may be generally free of epoxy resins and/or other conventional thermoset resins. For example, in such embodiments, additional thermoset resins (e.g., epoxy resins) may be present in an amount of no more than about 5 wt. %, in some embodiments no more than about 1 wt. %, and in some embodiments, from about 0.001 wt. % to about 0.5 wt. % of the polymer composition.

ii. Inorganic Fillers

If desired, an inorganic filler may also be employed in the polymer composition to help improve the dimensional stability and mechanical strength of the polymer composition. Examples of suitable inorganic fillers include, for instance, silica (fused, non-fused, porous, or hollow), aluminum oxide, aluminum hydroxide, magnesium oxide, magnesium hydroxide, calcium carbonate, aluminum nitride, boron nitride, aluminum silicon carbide, silicon carbide, sodium carbonate, titanium dioxide, zinc oxide, zirconium oxide, quartz, diamond powder, diamond-like powder, graphite, magnesium carbonate, potassium titanate, mica, boehmite, zinc molybdate, ammonium molybdate, zinc borate, calcium phosphate, talc, talc, silicon nitride, mullite, kaolin, clay, etc. Silica and alumina nitride may be particularly suitable for use in the polymer composition. When employed, inorganic fillers may constitute from about 0.5 to about 40 wt. %, in some embodiments from about 1 wt. % to about 35 wt. %, and in some embodiments, from about 5 wt. % to about 30 wt. % of the polymer composition. Nevertheless, one beneficial aspect of the present invention is that good dimensional stability may be achieved without the need for various conventional inorganic fillers, such as silica or aluminum nitride. In fact, in certain embodiments of the present invention, the polymer composition may be generally free of silica and/or other conventional inorganic fillers. For example, in such embodiments, inorganic fillers (e.g., silica, aluminum nitride, etc.) may be present in an amount of no more than about 0.5 wt. %, in some embodiments no more than about 0.1 wt. %, and in some embodiments, from about 0.001 wt. % to about 0.1 wt. % of the polymer composition.

iii. Flame Retardants

In certain embodiments, it may be desired that the polymer composition is generally fire resistant. In this regard, a flame-retardant may optionally be employed in the polymer composition. Flame retardants that have a low content of halogens (e.g., bromine, chlorine, and/or fluorine) are particularly suitable for use in the present invention. For example, the flame retardants, as well as the resulting polymer composition, may have a halogen content of about 500 parts per million by weight (“ppm”) or less, in some embodiments about 100 ppm or less, and in some embodiments, about 50 ppm or less. In certain embodiments, the flame retardants are free of halogens (i.e., “halogen free”).

One example of a suitable flame retardant, for instance, is an organophosphorous compound, such as a salt of phosphinic acid and/or diphosphinic acid (i.e., “phosphinate”) having the general formula (IV) and/or formula (V):

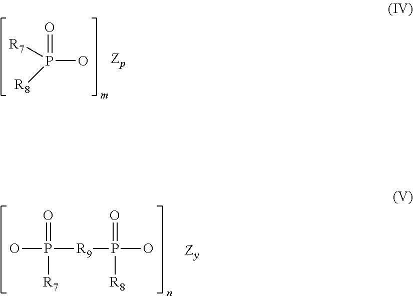

wherein,

R₇ and R₈ are, independently, hydrogen or substituted or unsubstituted, straight chain, branched, or cyclic hydrocarbon groups (e.g., alkyl, alkenyl, alkylnyl, aralkyl, aryl, alkaryl, etc.) having 1 to 6 carbon atoms, particularly alkyl groups having 1 to 4 carbon atoms, such as methyl, ethyl, n-propyl, iso-propyl, n-butyl, or tert-butyl groups;

R₉ is a substituted or unsubstituted, straight chain, branched, or cyclic C₁-C₁₀ alkylene, arylene, arylalkylene, or alkylarylene group, such as a methylene, ethylene, n-propylene, iso-propylene, n-butylene, tert-butylene, n-pentylene, n-octylene, n-dodecylene, phenylene, naphthylene, methylphenylene, ethylphenylene, tert-butylphenylene, methylnaphthylene, ethylnaphthylene, t-butylnaphthylene, phenylethylene, phenylpropylene or phenylbutylene group;

Z is a metal (e.g., magnesium, calcium, aluminum, antimony, tin, germanium, titanium, iron, zirconium, cesium, bismuth, strontium, manganese, lithium, sodium, potassium, etc.) or protonated nitrogen base;

m is from 1 to 4, in some embodiments from 1 to 3, and in some embodiments, from 2 to 3 (e.g., 3);

n is from 1 to 4, in some embodiments from 1 to 3, and in some embodiments, from 2 to 3 (e.g., 3);

p is from 1 to 4, in some embodiments from 1 to 3, and in some embodiments, from 1 to 2; and

y is from 1 to 4, in some embodiments from 1 to 3, and in some embodiments, from 1 to 2.

The phosphinates may, for instance, be prepared using any known technique, such as by reacting a phosphinic acid with metal carbonates, metal hydroxides or metal oxides in aqueous solution. Suitable phosphinates include, for example, salts (e.g., aluminum or calcium salt) of dimethylphosphinic acid, ethylmethylphosphinic acid, diethylphosphinic acid, methyl-n-propylphosphinic acid, methane-di(methylphosphinic acid), ethane-1,2-di(methylphosphinic acid), hexane-1,6-di(methylphosphinic acid), benzene-1,4-di(methylphosphinic acid), methylphenylphosphinic acid, diphenylphosphinic acid, hypophosphoric acid, etc. The resulting salts are typically monomeric compounds; however, polymeric phosphinates may also be formed. Additional examples of suitable phosphinic compounds and their methods of preparation are described in U.S. Pat. No. 7,087,666 to Hoerold, et al.; U.S. Pat. No. 6,716,899 to Klatt, et al.; U.S. Pat. No. 6,270,500 to Kleiner, et al.; U.S. Pat. No. 6,194,605 to Kleiner; U.S. Pat. No. 6,096,914 to Seitz; and U.S. Pat. No. 6,013,707 to Kleiner, et al.

Another suitable halogen-free organophosphorous flame retardant may be a polyphosphate having the following general formula:

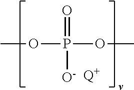

v is from 1 to 1000, in some embodiments from 2 to 500, in some embodiments from 3 to 100, and in some embodiments, from 5 to 50; and

Q is a nitrogen base. Suitable nitrogen bases may include those having a substituted or unsubstituted ring structure, along with at least one nitrogen heteroatom in the ring structure (e.g., heterocyclic or heteroaryl group) and/or at least one nitrogen-containing functional group (e.g., amino, acylamino, etc.) substituted at a carbon atom and/or a heteroatom of the ring structure. Examples of such heterocyclic groups may include, for instance, pyrrolidine, imidazoline, pyrazolidine, oxazolidine, isoxazolidine, thiazolidine, isothiazolidine, piperidine, piperazine, thiomorpholine, etc. Likewise, examples of heteroaryl groups may include, for instance, pyrrole, imidazole, pyrazole, oxazole, isoxazole, thiazole, isothiazole, triazole, furazan, oxadiazole, tetrazole, pyridine, diazine, oxazine, triazine, tetrazine, and so forth. If desired, the ring structure of the base may also be substituted with one or more functional groups, such as acyl, acyloxy, acylamino, alkoxy, alkenyl, alkyl, amino, aryl, aryloxy, carboxyl, carboxyl ester, cycloalkyl, hydroxyl, halo, haloalkyl, heteroaryl, heterocyclyl, etc. Substitution may occur at a heteroatom and/or a carbon atom of the ring structure. For instance, one suitable nitrogen base may be a triazine in which one or more of the carbon atoms in the ring structure are substituted by an amino group. One particularly suitable base is melamine, which contains three carbon atoms in the ring structure substituted with an amino functional group.

iv. Other Additives

If desired, the polymer composition may also employ one or more other types of additives. Examples of such additives may include, for instance, viscosity modifiers, antimicrobials, pigments, antioxidants, stabilizers, surfactants, waxes, flow promoters, solid solvents, and other materials added to enhance properties and processibility.

The amount of the aromatic polyester employed in forming the polymer composition may vary widely depending on the particular nature of the additives selected. In certain embodiments, for example, the aromatic polyester may form a substantial portion of the composition and serve as a major resinous component. In such cases, the aromatic polyester may, for instance, constitute from about 40 wt. % to about 95 wt. %, in some embodiments from about 50 wt. % to about 90 wt. %, and in some embodiments, from about 60 wt. % to about 85 wt. % of the composition. In yet other embodiments, however, the aromatic polyester may simply be used as a filler. In such cases, the aromatic polyester may constitute from about 0.5 to about 40 wt. %, in some embodiments from about 1 wt. % to about 35 wt. %, and in some embodiments, from about 5 wt. % to about 30 wt. % of the polymer composition.

### II. Fibrous Substrate

The fibrous substrate used in the prepreg composite of the present invention generally contains glass fibers, such as those formed from E-glass, A-glass, C-glass, D-glass, AR-glass, R-glass, S1-glass, S2-glass, etc. Glass fibers may, for instance, constitute about 50 wt. % or more, in some embodiments, about 75 wt. % or more, and in some embodiments, from about 85 wt. % to 100 wt. % of the fibers used to form the substrate. The fibrous substrate may be in the form of a fabric or cloth.

The void content of the fibrous substrate can vary as desired to achieve the desired degree of polymer impregnation. The void content may, for instance, range from about 30% to about 95%, in some embodiments from about 40% to about 92%, and in some embodiments, from about 50% to about 90%. The void content of the fibrous substrate can be determined by the following formula:

Void Content=[1−(D/D_{standard})]×100

wherein,

D is the bulk density (g/cm³) and is equal to W/V;

W is the mass of the fibrous substrate (grams);

V is the volume of the fibrous substrate (cm³), including the voids; and

D_{standard} is the density (g/cm³) for the material used to form the substrate without voids (e.g., 2.6 g/cm³ for glass).

The volume of the substrate is typically determined by multiplying its length, width, and thickness. The thickness of the substrate may be the average thickness, such as measured with a dial thickness gauge (e.g., “SM-1201” manufactured by Teclock Corporation when the only load applied is the main body spring load). The average thickness is generally from about 5 micrometers to about 500 micrometers, in some embodiments from about 20 micrometers to about 200 micrometers, in some embodiments from about 30 to about 150 micrometers, and in some embodiments, from about 40 to about 120 micrometers.

The manner in which the aforementioned polymer composition is incorporated into the fibrous substrate may vary as is known by those skilled in the art. In fact, one particular benefit of the present invention is that the aromatic polyester may remain relatively flowable and easy to process prior to crosslinking, which can provide a great degree of flexibility in the particular type of application method that is employed. For example, in certain embodiments, the fibrous substrate may be formed and thereafter contacted with the polymer composition, such as by dipping, powder coating, spraying, etc. In one particular embodiment, the polymer composition may be applied using a thermal spraying method, such as flame spraying, cold spraying, warm spraying, plasma spraying, etc. Thermal spraying generally involves the use of a working gas that is heated to a temperature lower than the melting point or softening temperature of the polymer composition. The gas is accelerated to supersonic velocity so that the composition is brought into collision with the substrate at a high velocity to form a coating thereon. During this process, the composition may be heated to a certain temperature (e.g., above the melting temperature). The composition may be supplied to the working gas along the coaxial direction with the gas at a feed rate, such as from about 1 to about 200 g/minute, and in some embodiments, from about 10 to about 100 g/minute. The distance between the substrate and the nozzle tip of the spray apparatus may be from about 5 to about 100 mm, and the traverse velocity of the nozzle may be from about 10 to about 300 min/second.

Once impregnated, the aromatic polyester may be crosslinked to form a thermoset polymer, which has enhanced thermal and mechanical properties. Crosslinking may occur at temperatures of about 380° C. or more, in some embodiments about 390° C. or more, and in some embodiments, 400° C. to about 450° C. Although not always the case, a small portion of the crosslinking agent may also remain unreacted and within the composition after crosslinking. For example, in certain embodiments, the crosslinking agent may constitute from about 0.001 wt. % to about 2 wt. %, and in some embodiments, from about 0.01 wt. % to about 1 wt. %, and in some embodiments, from about 0.05 wt. % to about 0.5 wt. % of the composition. It should of course be understood that the thermoset aromatic polyester may also be formed by crosslinking prior to forming the prepreg composite, if so desired. In certain embodiments, for instance, the polyester may be crosslinked after forming the polymer composition yet prior to formation of the composite. The aromatic polyester may also be crosslinked prior to incorporation into the polymer composition, such as during polymerization as noted above.

### III. Applications

The resulting prepreg composite can be employed in a wide variety of possible applications, such as multi-layer print wiring boards for semiconductor package and mother boards, printed circuit boards (e.g., rigid or rigid-flex), tape automated bonding, tag tape, packaging for microwave oven, shields for electromagnetic waves, probe cables, communication equipment circuits, MEMS devices, barrier products, clothing, filter media, etc. In one particular embodiment, for instance, the composite is employed in a printed circuit board. The composite may, for instance, be laminated to a conductive layer or to other laminate materials containing a conductive layer. The conductive layer may be in the form of a metal plate or foil, such as those containing gold, silver, copper, nickel, aluminum, etc. (e.g., copper foil). The composite may be laminated to the conductive layer using any known technique, such as ion beam sputtering, high frequency sputtering, direct current magnetron sputtering, glow discharge, etc.

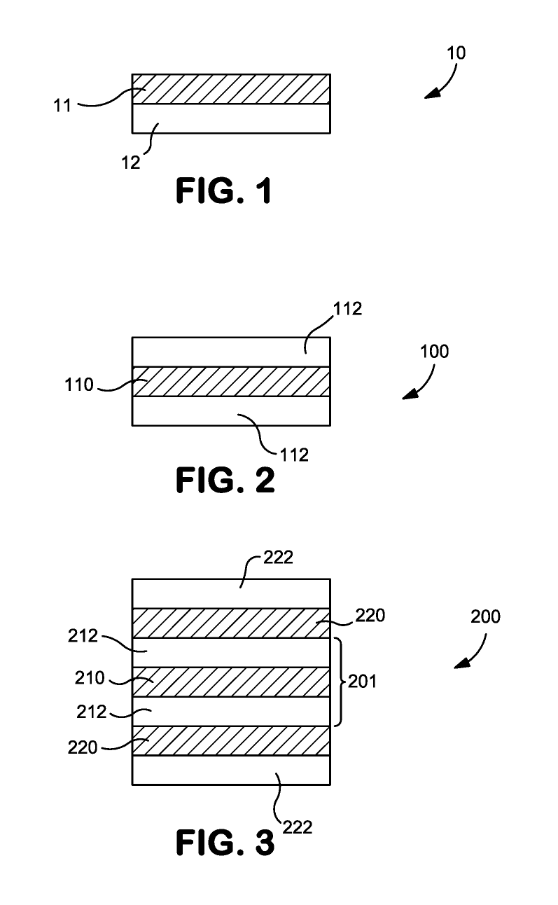

The laminate may have a two-layer structure containing only the composite and conductive layer. Referring to FIG. 1, for example, one embodiment of such a two layer structure 10 is shown as containing a composite 11 positioned adjacent to a conductive layer 12 (e.g., copper foil). Alternatively, a multi-layered laminate may be formed that contains two or more conductive layers and/or two or more prepreg composite layers. Referring to FIG. 2, for example, one embodiment of a three-layer laminate structure 100 is shown that contains a prepreg composite layer 110 positioned between two conductive layers 112. Yet another embodiment is shown in FIG. 3. In this embodiment, a seven-layered laminate structure 200 is shown that contains a core 201 formed from an insulating layer 210 positioned between two conductive layers 212. Insulating layers 220 likewise overlie each of the conductive layers 212, respectively, and external conductive layers 222 overlie the composite layers 220. In the embodiments described above, the prepreg composite of the present invention may be used to form any, or even all of the insulating layers. Further, the layers in the aforementioned embodiments may be attached together using techniques well known in the art, such as through the use of an adhesive. Various conventional processing steps may also be employed to provide the laminate with sufficient strength. For example, the laminate may be pressed and/or subjected to heat treatment as is known in the art.

Regardless of how it is formed, the resulting printed circuit board can be employed in a variety of different electronic components. As an example, printed circuit boards may be employed in desktop computers, cellular telephones, laptop computers, small portable computers (e.g., ultraportable computers, netbook computers, and tablet computers), wrist-watch devices, pendant devices, headphone and earpiece devices, media players with wireless communications capabilities, handheld computers (also sometimes called personal digital assistants), remote controllers, global positioning system (GPS) devices, handheld gaming devices, etc. Of course, the composite may also be employed in electronic components, such as described above, in devices other than printed circuit boards. For example, the composite may be used to form high density magnetic tapes, wire covering materials, etc.

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed is:

1. A prepreg composite comprising a fibrous substrate having a thickness of from about 5 to about 500 micrometers and containing glass fibers, wherein a polymer composition is impregnated within the fibrous substrate and that includes a crosslinked thermoset aromatic polyester, the aromatic polyester including repeating units derived from an aromatic hydroxycarboxylic acid, aromatic dicarboxycarboxylic acid, aromatic diol, aromatic amide, aromatic amine, or a combination thereof.

2. The prepreg composite of claim 1, wherein the aromatic polyester contains repeating units derived from naphthenic hydroxycarboxylic acids and/or naphthenic dicarboxylic acids.

3. The prepreg composite of claim 2, wherein the repeating units derived from naphthenic hydroxycarboxylic acids and/or naphthenic dicarboxylic acids constitute more than about 15 mol. % of the aromatic polyester.

4. The prepreg composite of claim 2, wherein the aromatic polyester contains repeating units derived from 6-hydroxy-2-naphthoic acid.

5. The prepreg composite of claim 4, wherein the aromatic polyester further contains repeating units derived from 4-hydroxybenzoic acid.

6. The prepreg composite of claim 5, wherein the aromatic polyester further comprises repeating units derived from hydroquinone and/or 4,4′-biphenol.

7. The prepreg composite of claim 1, wherein the aromatic polyester contains repeating units derived from 6-hydroxy-2-naphthoic acid in an amount from about 15 mol. % to about 60 mol. %, repeating units derived from 4-hydroxybenzoic acid in an amount from about 20 mol. % to about 65 mol. %, and repeating units derived from hydroquinone and/or 4,4′-biphenol in an amount from about 1 mol. % to about 40 mol. %.

8. The prepreg composite of claim 1, wherein the polyester is wholly aromatic.

9. The prepreg composite of claim 1, wherein the crosslinked aromatic polyester is formed by reacting an aromatic polyester with a crosslinking agent.

10. The prepreg composite of claim 9, wherein the crosslinking agent is an alkynyl compound.

11. The prepreg composite of claim 9, wherein the crosslinking agent is a maleimide compound.

12. The prepreg composite of claim 11, wherein the crosslinking agent is a bismaleimide having the following general formula: 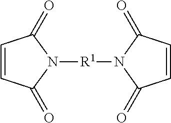
wherein R¹ is a substituted or unsubstituted, alkyl, alkenyl, alkynyl, cycloalkyl, aryl, heteroaryl, heterocyclyl, or a combination thereof.

13. The prepreg composite of claim 12, wherein R¹ is an aryl that contains one or more aromatic rings having from 6 to 15 carbon atoms.

14. The prepreg composite of claim 13, wherein R¹ contains two aromatic rings.

15. The prepreg composite of claim 14, wherein the bismaleimide is diphenylmethane bismaleimide, N,N′-(3,3′-dimethyl-4,4′-biphenylylene) bismaleimide, 3,3′-dichloro-4,4′-diphenylmethane bismaleimide, 3,3′-dimethyl-4,4′ diphenylmethane bismaleimide, 3,3′-dimethoxy-4,4′-diphenylmethane bismaleimide, 4,4′-diphenylsulfide bismaleimide, 4,4′-diphenylether bismaleimide, 3,3′-benzophenone bismaleimide, 3, 3′-dimethyl-5,5′-diethyl-4,4′-diphenylmethane bismaleimide, or a combination thereof.

16. The prepreg composite of claim 13, wherein R¹ contains one aromatic ring.

17. The prepreg composite of claim 16, wherein the bismaleimide is 4-methyl-1,3-phenylene bismaleimide, 1,3-phenylene bismaleimide, 1,4-phenylene bismaleimide, 1,2-phenylene bismaleimide, naphthalene-1,5-bismaleimide, 4-chloro-1,3-phenylene bismaleimide, or a combination thereof.

18. The prepreg composite of claim 1, wherein the composition is free of epoxy resins.

19. The prepreg composite of claim 1, wherein the composition is free of inorganic fillers.

20. The prepreg composite of claim 1, wherein the composition has a halogen content of 500 parts per million or less.

21. A laminate comprising the prepreg composite of claim 1 and a conductive layer.

22. The laminate of claim 21, wherein the conductive layer contains copper.

23. The laminate of claim 21, wherein the prepreg composite is positioned between two conductive layers.

24. A printed circuit board comprising the laminate of claim 21.
